(19) United States
(12) Patent Application Publication
(10) Pub. No.: US 2014/0191635 A1
(43) Pub. Date: Jul. 10, 2014

(54) ELECTRONIC DEVICE ENCLOSURE WITH HANDLE

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventor: ZHAN-YANG LI, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 14/029,797

(22) Filed: Sep. 18, 2013

(30) Foreign Application Priority Data
Jan. 7, 2013 (CN) 2013100044236

(51) Int. Cl. H05K 5/02

(52) U.S. Cl. CPC H05K 5/0221; H05K 5/023
USPC 312/223.1

(57) ABSTRACT

An electronic device enclosure includes a chassis, a cover secured to the chassis, a handle rotatably mounted to the chassis, and an operation member slidably mounted to the chassis. The cover includes a resilient piece. The operation member includes a resilient arm and a limiting block. The handle defines a latching slot, which engages with the limiting block. The resilient piece is elastically deformed to resist the handle. The operation member is operable to be slid relative to the chassis to disengage the limiting block from the latching slot, so that the resilient piece rebounds to open the handle.

### BACKGROUND

1. Technical Field

The present disclosure relates to an electronic device enclosure, and particularly to an electronic device enclosure with a handle.

2. Description of Related Art

Many electronic devices, such as servers, contain heavy electronic modules, such as power supplies and fan modules. The heavy electronic modules are secured in an enclosure of the electronic device. A handle may be rotatably mounted to the enclosure by a rotating shaft for conveniently moving the enclosure. However, when moving the enclosure, the handle often needs to be pulled out forcefully. Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of one embodiment of an electronic device enclosure.

FIG. 2 is an isometric view of an operation member of the electronic device enclosure of FIG. 1.

FIG. 3 is an assembled, isometric view of the electronic device enclosure of FIG. 1, with the operation member in a closed position and a handle secured by the operation member.

FIG. 4 is similar to FIG. 3, with a chassis and a cover partially cut.

FIG. 5 is an enlarged view of a circled portion V of FIG. 4.

FIG. 6 is another assembled, isometric view of the electronic device enclosure of FIG. 1, with the operation member in an open position and the handle opened.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

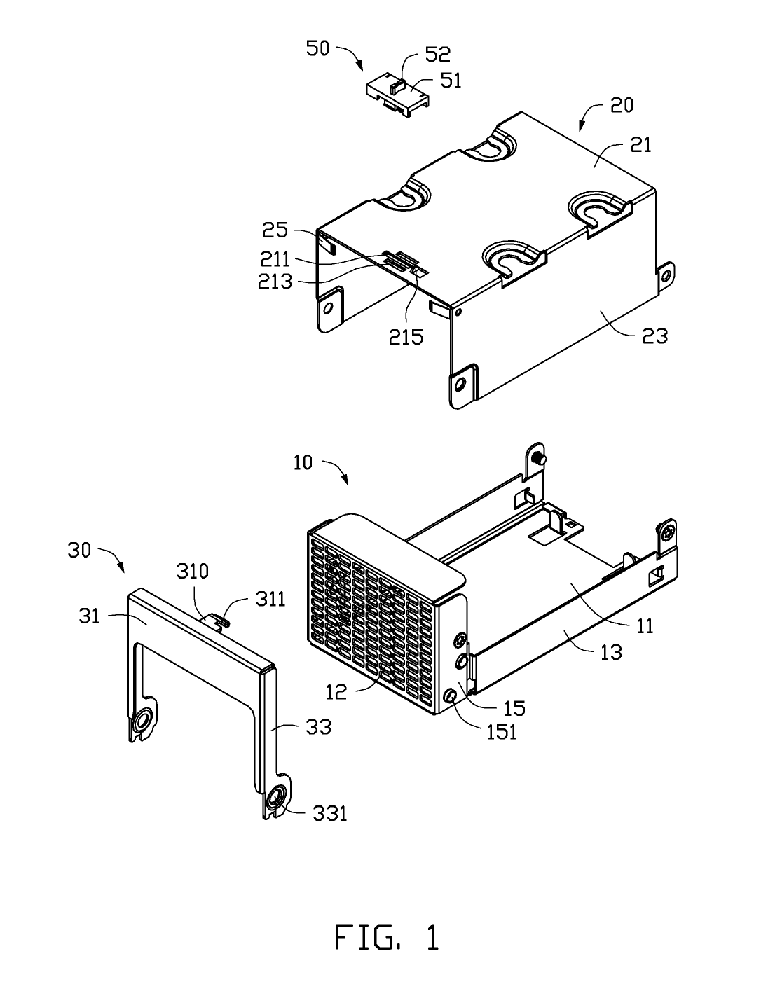

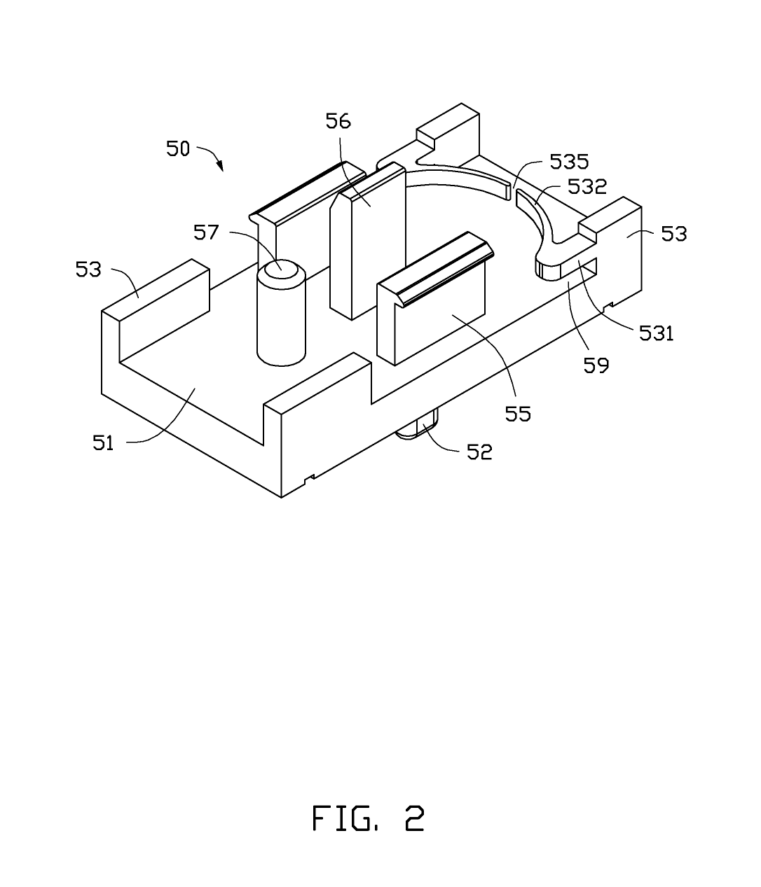

FIG. 1 and FIG. 2 show one embodiment of an electronic device enclosure for securing an electronic module (not shown). The electronic device enclosure includes a chassis 10, a cover 20, a handle 30, and an operation member 50.

The chassis 10 includes a bottom plate 11, a front plate 12, and two side plates 13. The two side plates 13 are opposite to each other. In this embodiment, the bottom plate 11 is substantially perpendicular to the front plate 12 and the side plates 13, and the front plate 12 is substantially perpendicular to the side plates 13. Two flanges 15 extend from opposite side edges of the front plate 12, respectively. The flanges 15 are substantially perpendicular to the bottom plate 11. Each flange 15 is riveted to a corresponding side plate 13. In this embodiment, the flange 15 is substantially parallel to the corresponding side plate 13. A pivoting shaft 151 is located on the flange 15.

The cover 20 includes a top wall 21 and two sidewalls 23. The top wall 21 defines a sliding slot 211 and two limiting slots 213. The sliding slot 211 is located between the two limiting slots 213. An extending direction of the sliding slot 211 is substantially parallel to an extending direction of each limiting slot 213. A blocking piece 215 extends upwards from the top wall 21. In this embodiment, the top wall 21 is substantially perpendicular to each sidewall 23 and the blocking piece 215. A resilient piece 25 extends from each sidewall 23. The resilient piece 25 extends slantingly out of the cover 20.

The handle 30 includes a mounting plate 31 and two rotating arms 33 connected to the mounting plate 31. A latching piece 310 is secured to the mounting plate 31. The latching piece 310 defines a latching slot 311. The latching slot 311 extends from a side edge of the latching piece 310. Each rotating arm 33 defines a pivoting hole 331. In this embodiment, the latching piece 310 is substantially perpendicular to the mounting plate 31, and an extending direction of the latching slot 311 is substantially parallel to an extending direction of the sliding slot 211.

The operation member 50 includes a sliding plate 51 and an operation piece 52 extending upwards from a top surface of the sliding plate 51. Four holding plates 53, two elastic hooks 55, a limiting block 56, and a limiting post 57 extend from a bottom surface of the sliding plate 51. The four holding plates 53 are located at four corners of the sliding plate 51, respectively. The two hooks 55 are adjacent to opposite edges of the sliding plate 51, respectively. The limiting block 56 and the limiting post 57 are located between the two hooks 55. An extending arm 531 extends from two adjacent holding blocks 53. The extending arm 531 is substantially parallel to the sliding plate 51. A resilient arm 532 is connected between the two extending arms 531. A gap 59 is defined between the sliding plate 51 and each extending arm 531. In this embodiment, the resilient arm 532 is substantially curved. The resilient arm 532 curves away from the limiting block 56. The resilient arm 532 defines a cutout 535.

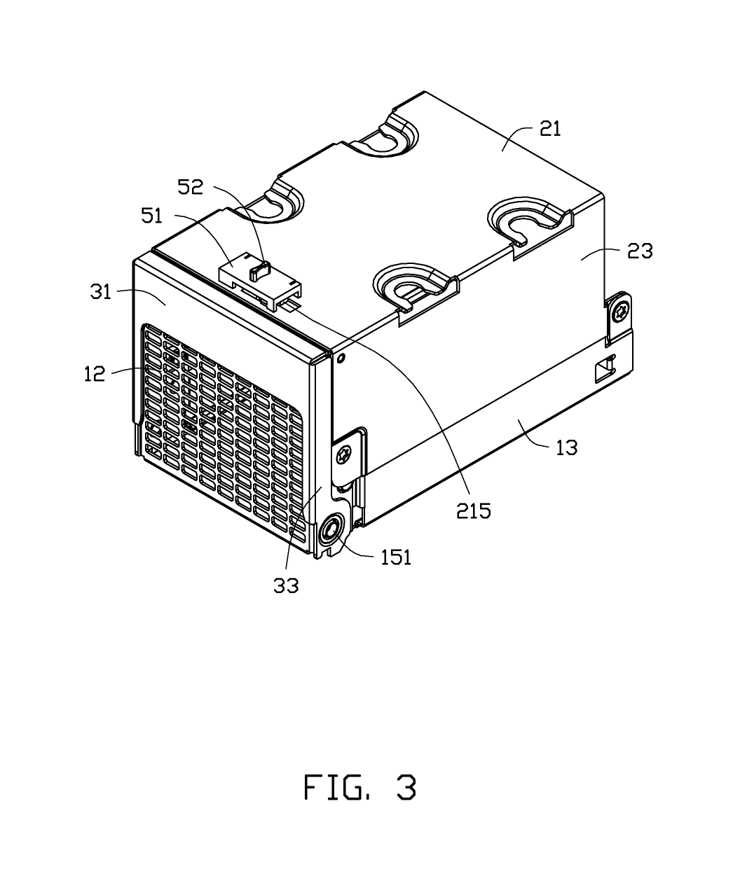

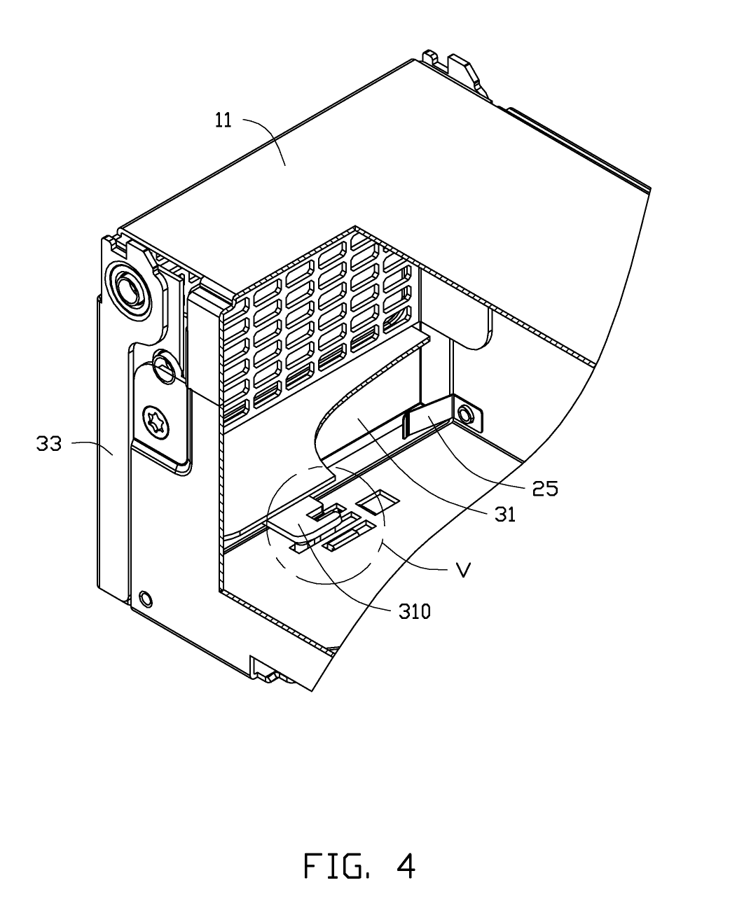

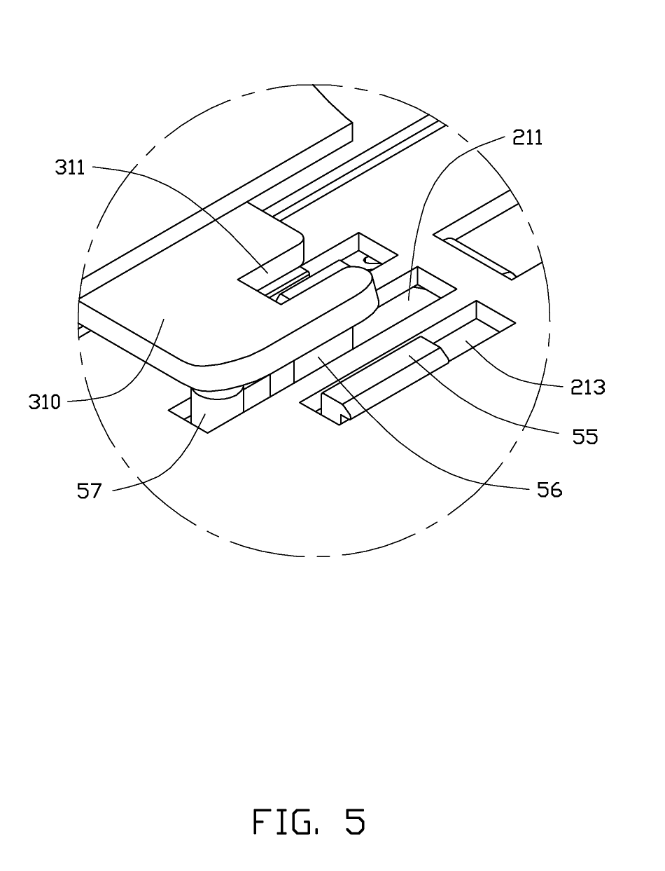

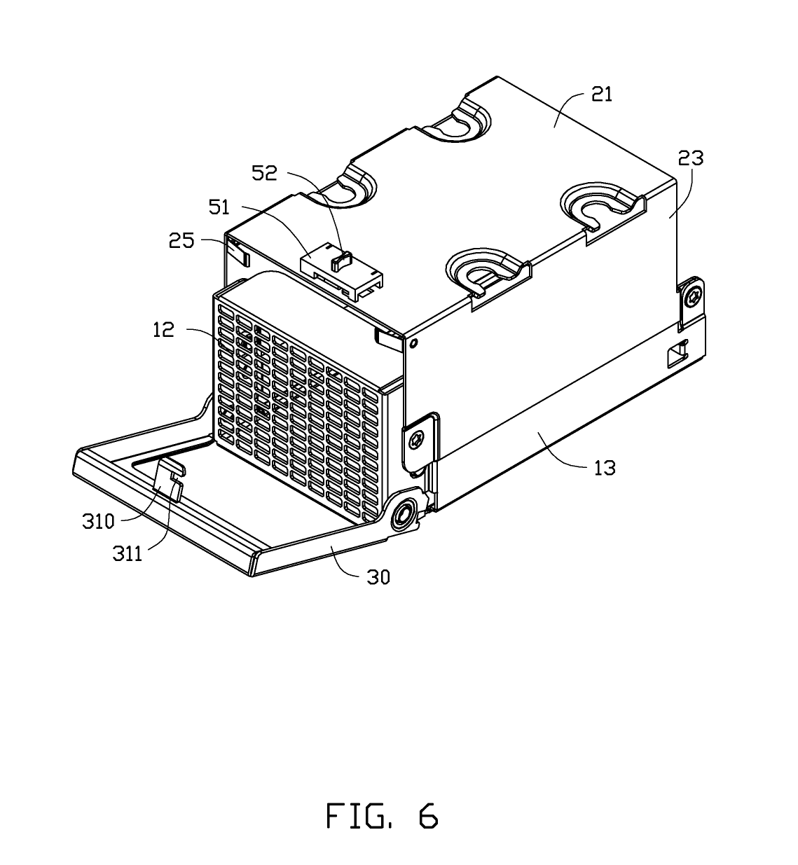

FIGS. 3-6 show that in assembly, the hooks 55 are aligned with the limiting slots 213, and the limiting block 56 and the limiting post 57 are aligned with the sliding slot 211. The operation member 50 is pressed downwards, the hooks 55 are elastically deformed to be received in the limiting slot 213, and the limiting block 56 and the limiting post 57 are received in the sliding slot 211. When the holding blocks 53 abut the top wall 21, the hooks 55 rebound to engage with a bottom surface of the top wall 21, thereby preventing the operation member 50 from detaching from the top wall 21. In this position, the operation member 50 is slidable relative to the cover 20, the hooks 55 are slidable in the limiting slots 213, and the limiting post 57 and the limiting block 56 are slidable in the sliding slot 211. The sidewalls 23 are secured to the flanges 15 by riveting, soldering, or other methods. The cover 20 covers the chassis 10. The pivoting shafts 151 are received by the pivoting holes 331 to rotatably mount the rotating arms 33 to the flanges 15.

In assembly of the handle 30, the operation member 50 is slid towards the blocking piece 215, until the resilient arm 532 is elastically deformed by the blocking piece 215. The handle 30 is rotated towards the front plate 12 and elastically deforms the resilient pieces 25. In this position, the latching piece 310 is extended into the cover 20, and the limiting block 56 is aligned with the latching slot 311. The operation member 50 is released, and the resilient arm 532 rebounds to slide the operation member 50 away from the blocking piece 215, until the limiting block 56 engages in the latching slot 311. Therefore, the handle 30 is secured to the chassis 10, and the operation member 50 is in a closed position.

To open the handle 30, the operation member 50 is slid towards the blocking piece 215, until the resilient arm 532 is elastically deformed. The resilient pieces 25 rebound to push the mounting plate 31 outwards, thereby releasing the handle 30 from the cover 20, and the operation member 50 is in an open position.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and the arrangement of parts within the principles of the disclosure, to the full extent indicated by the broad general meaning of the terms in which the appended claims are expressed.

What is claimed is:

1. An electronic device enclosure, comprising:
a chassis;
a cover secured to the chassis and comprising a resilient piece;
a handle rotatably mounted to the chassis and comprising a latching piece with a latching slot; and
an operation member slidably mounted on the chassis and comprising a resilient arm and a limiting block;
wherein a blocking piece extends from the chassis; the latching piece extends inside of the cover; the operation member is slidable between an open position and a closed position; when the operation member is in the closed position, the resilient arm is disengaged from the blocking piece, the limiting block is engaged in the latching slot, preventing the handle from being rotated relative to the chassis, the resilient piece is elastically deformed to resist the handle, and the operation member is slidable to disengage the limiting block from the latching slot to release the handle; and when the operation member is in the open position, the limiting block is disengaged from the latching slot, the resilient arm is elastically deformed to resist the blocking piece, and the resilient piece rebounds to rotate the handle relative to the chassis when the limiting block is disengaged from the latching slot.

2. The electronic device enclosure of claim 1, wherein the cover comprises a top wall, and the operation member is slidably mounted to the top wall; the operation member further comprises a sliding plate, and the limiting block extends from the sliding plate; and the top wall defines a sliding slot, and the limiting block is slidably received in the sliding slot.

3. The electronic device enclosure of claim 2, wherein an extending direction of the latching slot is substantially parallel to an extending direction of the sliding slot.

4. The electronic device enclosure of claim 2, wherein the blocking piece extends from the top wall and is substantially perpendicular to the top wall.

5. The electronic device enclosure of claim 2, wherein the operation member further comprises a hook extending from the sliding plate, the top wall further defines a limiting slot, and the hook engages with an inner surface of the top wall through the limiting slot, preventing the operation member from moving along a direction substantially perpendicular to the top wall.

6. The electronic device enclosure of claim 2, wherein the operation member further comprises a holding block extending from the sliding plate, and the holding block abuts the top wall.

7. The electronic device enclosure of claim 6, wherein the operation member further comprises an extending arm extending from the holding block, and the resilient arm extends from the extending arm; a gap is defined between the sliding plate and the extending arm, and the gap extends between the resilient arm and the sliding plate.

8. The electronic device enclosure of claim 7, wherein the resilient arm extends away from the limiting block, and the resilient arm is curved.

9. The electronic device enclosure of claim 2, wherein the operation member further comprises an operation piece extending from the sliding plate, and the operation piece is operable to slide the operation member.

10. The electronic device enclosure of claim 2, wherein the operation member further comprises a limiting post extending from the sliding plate, and the limiting post is slidably received in the sliding slot.

11. An electronic device enclosure, comprising:
a chassis;
a cover secured to the chassis and comprising a resilient piece;
a handle rotatably mounted to the chassis and comprising a latching piece with a latching slot; and
an operation member slidably mounted on the chassis and comprising a resilient arm, and a limiting block;
wherein a blocking piece extends from the chassis; the latching piece extends inside of the cover; the limiting block is engaged in the latching slot; the handle is fixed to the chassis; the resilient arm is disengaged from the blocking piece; the resilient piece is elastically deformed to resist the handle; the operation member is slidable relative to the chassis to elastically deform the resilient arm to resist the blocking piece and disengage the limiting block from the latching slot; and when the limiting block is disengaged from the latching slot, the resilient piece rebounds to rotate the handle, so as to open the handle.

12. The electronic device enclosure of claim 11, wherein the cover comprises a top wall, and the operation member is slidably mounted to the top wall; the operation member further comprises a sliding plate, and the limiting block extends from the sliding plate; and the top wall defines a sliding slot, and the limiting block is slidably received in the sliding slot.

13. The electronic device enclosure of claim 12, wherein an extending direction of the latching slot is substantially parallel to an extending direction of the sliding slot.

14. The electronic device enclosure of claim 12, wherein the blocking piece extends from the top wall and is substantially perpendicular to the top wall.

15. The electronic device enclosure of claim 12, wherein the operation member further comprises a hook extending from the sliding plate, the top wall further defines a limiting slot, and the hook engages with an inner surface of the top wall through the limiting slot, preventing the operation member from moving along a direction substantially perpendicular to the top wall.

16. The electronic device enclosure of claim 12, wherein the operation member further comprises a holding block extending from the sliding plate, and the holding block abuts the top wall.

17. The electronic device enclosure of claim 16, wherein the operation member further comprises an extending arm extending from the holding block, and the resilient arm extends from the extending arm; a gap is defined between the sliding plate and the extending arm, and the gap extends between the resilient arm and the sliding plate.

18. The electronic device enclosure of claim 17, wherein the resilient arm extends away from the limiting block, and the resilient arm is curved.

19. The electronic device enclosure of claim 12, wherein the operation member further comprises an operation piece extending from the sliding plate, and the operation piece is operable to slide the operation member.

20. The electronic device enclosure of claim 12, wherein the operation member further comprises a limiting post extending from the sliding plate, and the limiting post is slidably received in the sliding slot.
